(19) United States
(12) Patent Application Publication
(10) Pub. No.: US 2012/0160663 A1
(43) Pub. Date: Jun. 28, 2012

(54) Sputter Deposition and Annealing of High Conductivity Transparent Oxides

(75) Inventors: Dane GILLASPIE, Golden, CO (US); Thomas Gennett, Denver, CO (US); David S. Ginley, Evergreen, CO (US); John Perkins, Boulder, CO (US)

(73) Assignee: Alliance for Sustainable Energy, LLC., Golden, CO (US)

(21) Appl. No.: 13/324,835

(22) Filed: Dec. 13, 2011

Related U.S. Application Data
(60) Provisional application No. 61/422,741, filed on Dec. 14, 2010.

(51) Int. Cl. C23C 14/34

(52) U.S. Cl. 204/192.15

(57) ABSTRACT

Sputtering deposition processes for generation of transparent conductive metal oxide films, and films produced by such methods, are disclosed.

### CROSS-REFERENCE TO RELATED APPLICATION

This application claims priority to U.S. Provisional Application No. 61/422,741, filed Dec. 14, 2010, the contents of which are incorporated by reference in their entirety.

### CONTRACTUAL ORIGIN

The United States Government has rights in this invention under Contract No. DE-AC36-08G028308 between United States Department of Energy and the Alliance for Sustainable Energy, LLC, the Manager and Operator of the National Renewable Energy Laboratory.

### BACKGROUND

Transparent conducting oxides are doped metal oxides typically used in optoelectronic devices such as photovoltaics, semiconductors and flat panel displays. In operation, transparent conducting oxides act both as a window for light to pass through to an active material underneath the conducting oxide, where carrier generation occurs, and/or as an ohmic contact for carrier transport out of a device incorporating the conducting oxide. Transparent conducting oxides presently used in the industry are primarily n-type conductors, where their primary conduction is from the flow of electrons.

There are several types of transparent conducting oxides that are of commercial importance, many of which are produced using polycrystalline and/or amorphous microstructures. The current industry standard for the generation of transparent conducting oxides is tin-doped indium-oxide, which displays low resistivity and high transmittance. However, tin-doped indium-oxide has the drawback of being an expensive material. Indium is a rare post-transition metal having a price that can fluctuate greatly due to market demand. For this reason, other doped binary compounds have been used to produce transparent conducting oxides, including aluminum-doped zinc-oxide and indium-doped cadmium-oxide.

Fluorine-doped tin oxide is also used in the generation of transparent conducting oxides. However, it can be difficult to generate transparent fluorine-doped tin oxide films using existing current commercial manufacturing methods such as spray pyrolysis or chemical vapor deposition processes. This is because known commercial manufacturing methods, when employed at standard atmospheric pressures, tend to yield conducting oxide films with rough and/or diffusive surface morphologies. This produces a great disadvantage to the resulting conducting oxides, because the transmittance of transparent conducting oxides can be dramatically decreased by light scattering at defects and grain boundaries on the film.

During deposition of fluorine-doped tin oxide onto a target, typical chemical vapor deposition processes can cause the tin to agglomerate and collect in lumps along the target surface. Such defects not only result in poor transparency, as the fluorine-doped tin oxide coating looks hazy, but can also limit the transmittance of such films due to light scattering at the points of defect. Additionally, the resulting conducting tin oxide films are poor substrates for most semiconductor chips and other electrical devices such as, for example, photovoltaic cells, as they can hinder and/or reduce their conductive performance.

Further, most known chemical vapor deposition processes require very high operating temperatures, typically on the order of 400° C.-600° C. Achieving such high temperatures requires a large amount of energy and can be expensive to maintain for long periods of time. Additionally, such elevated temperatures tend to cause damage to the underlying layers in multilayer devices having a conducting oxide top layer, which has deleterious effects on device performance. Because of this, the use of fluorine-doped tin oxide as a top layer conductor for semiconductors, photovoltaic cells and similar devices has been limited.

The foregoing examples of the related art and limitations related therewith are intended to be illustrative and not exclusive. Other limitations of the related art will become apparent to those of skill in the art upon a reading of the specification and a study of the drawings.

### SUMMARY

Thus, alternate methods of generating transparent conducting oxides, such as sputtering techniques and/or sputtering techniques followed by an annealing step, are useful. The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

In various aspects, methods for sputter deposition of a tin-oxide film onto a substrate are provided. The methods comprising providing a tin compound in a sputtering chamber; providing a substrate in the sputtering chamber; introducing at least one inert gas into the sputtering chamber; maintaining the temperature of the sputtering chamber below about 100° C.; energizing the tin compound and the at least one inert gas with radio frequency energy; and sputtering the tin oxide as a film onto the substrate.

In some embodiments the methods also comprise energizing the tin compound with direct current concurrently with the radio frequency energy. In some embodiments, the tin compound is selected from tin metal, tin oxide, tin fluoride, and combinations thereof.

The methods can also comprise, prior to the step of energizing: introducing at least one gas selected from halogen gases and halogen-containing gases into the sputtering chamber; energizing the halogen gas with the radio frequency energy; and sputtering the halogen from the at least one gas onto the substrate concurrently with the tin oxide.

In some embodiments, the at least one gas is fluorine gas and the amount of fluorine gas is adjusted stoichiometrically to compensate for a metal versus an oxide target. In some embodiments, the at least one gas is carbon tetrafluoride gas and the concentration of the carbon tetrafluoride gas in the sputtering chamber is between approximately 0.5% and 1.5%.

The methods can also comprise introducing oxygen gas into the sputtering chamber, wherein the concentration of oxygen gas is adjusted stoichiometrically to compensate for a metal versus an oxide target. In some embodiments, the concentration of the oxygen gas in the sputtering chamber is between approximately 0.1% and 0.4%.

In some embodiments, the inert gas is argon gas.

In some embodiments, the tin compound and the substrate are located between about 1.5-2 inches apart.

In some embodiments, the temperature of the sputtering chamber is maintained below about 45° C.

In some embodiments, the sputtering chamber is placed under a vacuum.

In various aspects, the present disclosure provides methods of generating a metal oxide film on a substrate. In some embodiments, the methods comprise: placing a metal oxide target material in a sputtering chamber; placing a substrate in the sputtering chamber at a distance from the metal oxide target; introducing at least one inert gas into the substrate chamber; adjusting the temperature of the sputtering chamber to below about 100° C.; energizing the metal oxide target and at least one inert gas via an energy source; and sputtering atoms from the metal oxide target onto the substrate.

In some embodiments, the metal oxide is selected from indium oxide, zinc oxide, cadmium oxide, tin oxide and combinations thereof.

In some embodiments, the substrate is selected from glass, ceramic, plastic, a silicon wafer, a photovoltaic cell and a semiconductor.

In some embodiments, the distance is between about 1.5-2 inches apart.

In some embodiments, the inert gas is selected from oxygen gas, helium gas, neon gas, argon gas, krypton gas, xenon gas, radon gas, and combinations thereof.

In some embodiments, the energy source is selected from pulsed direct current (DC), non-pulsed DC, alternating current (AC), high frequency AC/radio frequency (RF) energy, RF energy superimposed with DC, and combinations thereof.

In some embodiments, the temperature of the sputtering chamber is room temperature.

In some embodiments, the methods also comprise, prior to the step of energizing, introducing at least one gas selected from halogen gases and halogen-containing gases into the sputtering chamber.

In some embodiments, the halogen gases are selected from fluorine gas, chlorine gas, bromine gas, iodine gas, astatine gas and combinations thereof and the halogen-containing gases are selected from carbon tetrafluoride gas, carbon tetrachloride gas, carbon tetrabromide gas, carbon tetraiodide gas, carbon tetraastatine gas and combinations thereof.

In some embodiments, the halogen from the at least one gas is sputtered onto the substrate.

In various aspects, the present disclosure relates to methods for sputter deposition of a tin-oxide film onto a substrate. In some embodiments, the methods comprise: providing a tin compound in a sputtering chamber; providing a substrate in the sputtering chamber; introducing at least one inert gas into the sputtering chamber; maintaining the temperature of the sputtering chamber below about 100° C.; energizing the tin compound and the at least one inert gas with radio frequency energy; sputtering the tin oxide as a film onto the substrate; and annealing the sputtered film.

In some embodiments, the tin compound is energized with direct current concurrently with the radio frequency energy.

In some embodiments, the annealing is conducted at a temperature between about 250° C.-500° C. and between approximately 5-15 minutes.

In some embodiments, the tin compound is selected from tin metal, tin oxide, tin fluoride, and combinations thereof.

The methods can also comprise, prior to the step of energizing: introducing at least one gas selected from halogen gases and halogen-containing gases into the sputtering chamber; energizing the halogen gas with the radio frequency energy; and sputtering the halogen from the at least one gas onto the substrate concurrently with the tin oxide; wherein the halogen is annealed concurrently with the sputtered film.

In some embodiments, the at least one gas is fluorine gas.

In some embodiments, the at least one gas is carbon tetrafluoride gas and the concentration of the carbon tetrafluoride gas in the sputtering chamber is between approximately 0.5% and 1.5%.

In some embodiments the methods comprise, prior to the step of energizing, introducing oxygen gas into the sputtering chamber, wherein the concentration of the oxygen gas in the sputtering chamber is between approximately 0.1% and 0.4%.

In some embodiments, the inert gas is argon gas.

In some embodiments, the tin compound and the substrate are located between about 1.5-2 inches apart.

In some embodiments, the temperature of the sputtering chamber is maintained at below about 45° C. during sputtering.

In some embodiments, the sputtering chamber is placed under a vacuum.

In various aspects, the present disclosure relates to methods of generating a metal oxide film on a substrate. In some embodiments, the methods comprise: placing a metal oxide target material in a sputtering chamber; placing a substrate in the sputtering chamber at a distance from the metal oxide target; introducing at least one inert gas into the substrate chamber; adjusting the temperature of the sputtering chamber to below about 100° C.; energizing the metal oxide target and at least one inert gas via an energy source; sputtering atoms from the metal oxide target onto the substrate; and annealing the sputtered metal oxide.

In some embodiments, the annealing is conducted at a temperature between about 250° C.-500° C. and between approximately 5-15 minutes.

In some embodiments, the metal oxide is selected from indium oxide, zinc oxide, cadmium oxide, tin oxide and combinations thereof.

In some embodiments, the substrate is selected from glass, ceramic, plastic, a silicon wafer, a photovoltaic cell and a semiconductor.

In some embodiments, the distance is between about 1.5-2 inches apart.

In some embodiments, the inert gas is selected from oxygen gas, helium gas, neon gas, argon gas, krypton gas, xenon gas, radon gas, and combinations thereof.

In some embodiments, the energy source is selected from pulsed direct current (DC), non-pulsed DC, alternating current (AC), high frequency AC/radio frequency (RF) energy, RF energy superimposed with DC, and combinations thereof.

In some embodiments, the temperature of the sputtering chamber during sputtering is room temperature.

The methods can further comprise, prior to the step of energizing, introducing at least one gas selected from halogen gases and halogen-containing gases into the sputtering chamber.

In some embodiments, the halogen gases are selected from fluorine gas, chlorine gas, bromine gas, iodine gas, astatine gas and combinations thereof and the halogen-containing gases are selected from carbon tetrafluoride gas, carbon tetrachloride gas, carbon tetrabromide gas, carbon tetraiodide gas, carbon tetraastatine gas and combinations thereof.

In some embodiments, the halogen from the at least one gas is sputtered onto the substrate.

In addition to the exemplary aspects and embodiments described above, further aspects and embodiments will become apparent by reference to the drawings and by study of the following descriptions.

### BRIEF DESCRIPTION OF THE DRAWINGS

Those skilled in the art will understand that the drawings, described herein, are for illustration purposes only. The drawings are not intended to limit the scope of the present disclosure.

FIG. 1 is a schematic diagram of an exemplary sputter deposition chamber using both radio frequency (RF) and direct current (DC) energy.

FIG. 2 is a flow diagram of an exemplary process for sputtering a high conductivity tin oxide layer onto a target substrate at low temperatures.

FIG. 3 is a bar graph depicting the conductivity of sixteen individual transparent conductive tin oxide deposition samples, in which various parameters were changed for each individual sample, as indicated in Example 1.

FIG. 4A depicts a transparent conductive tin oxide sample generated by a standard chemical vapor deposition (CVD) process and is used as a basis for comparison for FIGS. 4B-4F, which depict secondary ion mass spectrometry (SIMS) measurements for five individual transparent conductive tin oxide deposition samples generated pursuant to the methods disclosed herein, and the resultant conductivity measurement for each completed sample.

FIG. 5 is a plot depicting the effect of the ambient temperature of the sputtering environment for three separate test samples of the transparent conducting tin oxide deposition processes disclosed herein.

FIG. 6 is a plot depicting the effect of distance between the metal oxide target material and the substrate in the sputtering chamber for two test samples produced by the conductive oxide deposition processes disclosed herein.

FIG. 7 is a plot depicting the effects of water vapor pressure on the conductivity of individual test samples of transparent conductive tin oxide films deposited pursuant to the methods disclosed herein.

FIG. 8 is a plot depicting the effects of varying the oxygen gas concentration in the plasma for five individual transparent conductive tin oxide film depositions performed according to the methods disclosed herein.

FIG. 9 is a plot of transmission characteristics of three transparent conductive tin oxide film deposition samples across the visible wavelength spectrum.

FIG. 10 is a plot of conductivity measurements for an annealing process conducted on a single transparent conducting tin oxide film sample after completion of a radio frequency (RF), room temperature sputtering process as disclosed herein.

### DETAILED DESCRIPTION

Reference is now made in detail to certain embodiments of methods of generating transparent conducting metal oxides by sputtering and the resulting transparent conducting oxide films. The disclosed embodiments are not intended to be limiting of the claims. To the contrary, the claims are intended to cover all alternatives, modifications, and equivalents.

In several aspects, the present disclosure relates to methods for creating transparent conducting oxide films by sputtering a target metal oxide onto a substrate. In some embodiments, the transparent conducting oxide films may be generated with a dopant. In alternate embodiments, the transparent conducting oxide films may be generated without a dopant. In various aspects, the transparent conducting oxide films can be tin-oxide conducting films.

In an exemplary embodiment, transparent conducting oxides films are generated by sputter deposition onto a substrate surface. The sputtering process can be performed at low temperatures including, without limitation, temperatures less than about 100° C., and, in some embodiments, at room temperature. A target comprising a metal oxide is placed inside of a sputtering chamber along with a substrate. One or more inert working gases are introduced into the sputtering chamber in advance of the sputtering process to facilitate sputtering. In some embodiments, one or more halogen gases and/or halogen-containing gases are also introduced into the sputtering chamber in advance of the sputtering process. The temperature of the sputtering chamber is adjusted to below about 100° C. and maintained at such temperature for the entirety of the sputtering process. The metal oxide target is then energized via an energy source such that the metal oxide atoms and/or ions are freed from the metal oxide material and sputtered onto the exposed surfaces of the substrate. In those embodiments where one or more halogen gases and/or halogen-containing gases are also introduced into the sputtering chamber, halogen ions are also sputtered onto the exposed substrate surfaces. The halogen ions act as a dopant to the metal oxide. In some embodiments, the metal oxide is energized with radio frequency (RF) energy. In some embodiments, the metal oxide is energized with direct current (DC) energy. And in some embodiments, the metal oxide is energized with a combination of RF and DC energy. The resulting transparent conducting metal oxide film, deposited onto the substrate surface, displays high conductivity and/or low resistivity.

In another exemplary embodiment, the sputtering process also includes an annealing step wherein the exemplary embodiment described above is concluded by annealing the metal oxide to the substrate surface.

The sputtering deposition methods disclosed herein are capable of generating transparent conducting oxide films that demonstrate high conductivity. The disclosed methods represent a significant advantage over other, known methods in that they do not require high temperatures that can cause damage to underlying layers in a device. The disclosed methods also provide a transparent conducting film without lumps of metal or metal oxide, thereby providing a film that is smooth and more transparent in appearance.

### Sputtering

Sputtering is a process of atomizing or eroding a solid target material. Sputter deposition is a method of generating a thin film on a substrate surface by sputtering, or eroding, material from a target. Typically, sputtering occurs by bombarding a target material with an energy source of some form, such as electrical energy or radio frequency energy. Upon such bombardment, atoms of the target material are ejected from the target into the surrounding atmosphere where they may be collected onto a substrate surface. Sputtering can be used for thin-film deposition, etching and analytical techniques, among other things.

The atoms of the target material are driven from the target by momentum exchange between the ions and/or atoms in the target. These ions and/or atoms are provided with such momentum by the energy bombardment. When the target is bombarded with energy, the ions and/or atoms gain momentum from the energy source which in turn causes collisions between neighboring atoms that are sufficient to free the ions and/or atoms from the solid target material. The freed atoms and/or ions are known as sputtered material. The sputtered material deposits onto a substrate surface such as, for example, a silicon wafer.

Sputtered atoms and/or ions are ejected from the target material into a plasma or gas-like phase. These atoms and/or ions of target material are not in thermodynamic equilibrium, and thus will deposit on any available surface in order to attain equilibrium. A substrate placed inside of the chamber will be coated with a thin film of the plasma ejected from the target material. Typically sputtering is carried out inside of a chamber so that the environment within the chamber can be controlled. It is common for sputtering to occur in a chamber that is under vacuum.

The sputtering process is thus initiated by applying power, in the form of an energy source, to a target material. The energy source can be of any type that generates sufficient momentum between neighboring atoms to free them from the target material including, for example, pulsed direct current (DC), non-pulsed DC, radio frequency (RF) energy, and RF energy superimposed with DC, among others. Erosion of the target material results from energetic particle bombardment by either reactive or non-reactive ions produced in the discharge.

Sputtered atoms ejected from a target material can have a wide energy distribution, typically up to tens of electron volts (eV) (100,000 K). The sputtered atoms fly ballistically from the target material and impact energetically onto opposing substrate surfaces. When present inside of a sputtering chamber in the form of a working gas plasma (a partially ionized gas of ions, electrons, and neutral species), the atoms and ions freed from the target material collide with gas atoms present inside of the sputtering chamber. The gas atoms comprising the plasma act as a moderator for the target atoms and ions which move diffusively through the sputtering chamber. When the target material reaches a substrate surface, it forms a thin film along the surface of the substrate via nucleation, a localized thermodynamic phase change from a gaseous-like state to a crystalline, polycrystalline and/or amorphous microstructure.

The duration of the sputtering process controls the thickness of the transparent conducting oxide film. Shorter sputtering times yield thin films while longer sputtering times yield thicker films.

A magnetron assembly can be used inside of the sputtering chamber to enhance the sputtering rate. A magnetron is a high-powered vacuum tube capable of generating microwaves via the interaction of a stream of electrons within a magnetic field. The magnetron acts to increase the ionizing effect of electrons magnetically trapped in the vicinity of the target. The magnetic field generated by the magnetron serves to trap the plasma near the surface of the target material so that the plasma does not strongly interact with the substrate, thereby allowing the atoms freed from the metal oxide target material to fly ballistically from the target to the substrate largely unimpeded. This results in improved film quality and increased deposition rate.

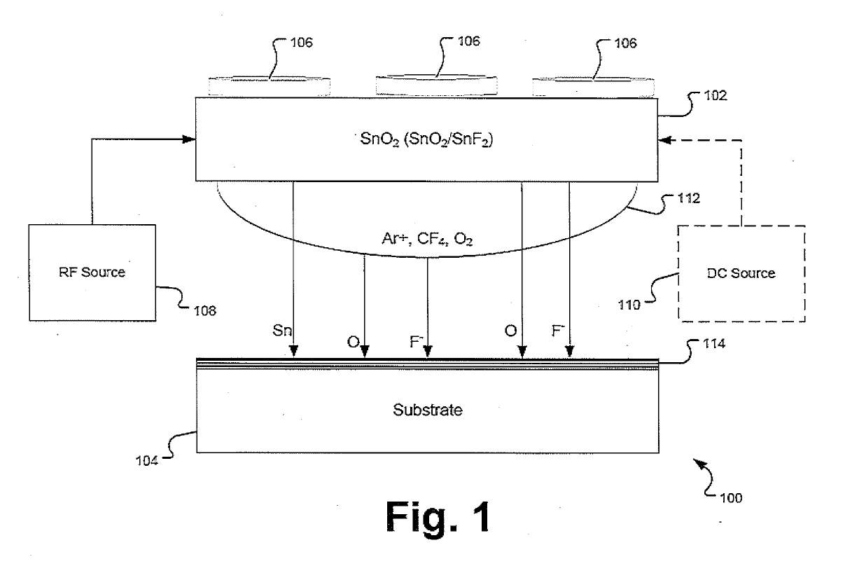

In various aspects, the present disclosure relates to the generation of transparent conducting oxide films by sputtering. FIG. 1 depicts a schematic diagram of an exemplary sputtering system 100 according to the present disclosure. The sputtering system 100 includes a magnetron, which is used to enhance the sputtering rate of atoms from a target material.

The sputtering system 100 comprises a cathode 102 in connection with a metal oxide target material and an anode 104 that is also a substrate having one or more surfaces that are to be coated with a transparent conducting oxide. At least one magnet 106 is, and in some embodiments a plurality of magnets 106 are, mounted adjacent to the metal oxide target material in order to create a magnetic flux around the cathode target 102. An energy source 108 is coupled to both the cathode target 102 and the anode substrate 104 to create an ionized electric field between them.

The cathodic metal oxide target material 102 can be any one or more of a number of metal oxides suitable for generation of transparent conducting metal oxide films. In some embodiments, the metal oxide target material is selected from indium oxide, zinc oxide, cadmium oxide, tin oxide and combinations thereof. In some embodiments, the metal oxide target material is selected from an oxide of any one or more of the Period 4 and/or Period 5 transition metals including, without limitation, scandium oxide, titanium oxide, vanadium oxide, chromium oxide, manganese oxide, iron oxide, cobalt oxide, nickel oxide, copper oxide, zinc oxide, gallium oxide, germanium oxide, yttrium oxide, zirconium oxide, niobium Oxide, molybdenum oxide, technetium oxide, ruthenium oxide, rhodium oxide, palladium oxide, silver oxide, cadmium oxide, indium oxide, tin oxide, antimony oxide and combinations thereof. In some embodiments, the metal oxide target material is tin oxide. The metal oxide target material may also be a doped metal oxide, whereby a dopant is utilized during the sputtering process as described herein. In the embodiment depicted in FIG. 1, the metal oxide target material is tin oxide and/or fluorine-doped tin oxide.

The anodic substrate material 104 can be any one or more of a number of substrates suitable for deposition of a transparent conducting oxide film. In some embodiments, the substrate is selected from glass, ceramic, plastic, silicon wafer material, and related materials. In some embodiments, the substrate is a photovoltaic cell. In some embodiments, the substrate is a semiconductor. In some embodiments, the substrate is a wafer.

The energy source 108 can be any one or more of a number of energy sources that generate sufficient momentum between neighboring atoms of the target material to free them from the target material. In some embodiments, the energy source is selected from pulsed direct current (DC), non-pulsed DC, alternating current (AC), high frequency AC/radio frequency (RF) energy, RF energy superimposed with DC, and combinations thereof. In the high frequency range, AC is referred to as RF energy. In some embodiments, the energy source is RF energy superimposed with DC. In the embodiment depicted in FIG. 1, the energy source is RF energy, however it is also possible to power the depicted sputtering system 100 using a DC power source or the RF energy source in connection with the DC energy source.

The sputtering system 100 can be maintained in any state of pressure suitable for deposition of transparent conducting oxide films. In some embodiments, the pressure of the sputtering system 100 is selected from greater than atmospheric pressure, atmospheric pressure, less than atmospheric pressure and a vacuum. In some embodiments, the sputtering system 100 is maintained in a high vacuum state during sputtering.

The distance between the metal oxide target material 102 and the anodic substrate 104 can be varied. In some embodiments, the distance between the metal oxide target material 102 and the anodic substrate material 104 ranges from 0 to about 3 inches. In some embodiments, the distance between the metal oxide target material 102 and the anodic substrate material 104 ranges from about 0.5 to about 2.5 inches. In some embodiments, the distance between the metal oxide target material 102 and the anodic substrate material 104 ranges from about 1.0 to about 1.5 inches.

To initiate sputtering, a desired pressure is placed on the sputtering system 100 and the energy source 108 is activated, thereby energizing the metal oxide target 102.

The temperature of the sputtering system 100 during the sputtering process can be controlled. In some embodiments, the temperature of the sputtering system 100 during the sputtering process is maintained at a temperature of less than about 100° C. In some embodiments, the temperature of the sputtering system 100 during the sputtering process is maintained at a temperature selected from about 99° C., about 95° C., about 90° C., about 85° C., about 80° C., about 75° C., about 70° C., about 65° C., about 60° C., about 55° C., about 50° C., about 45° C., about 40° C., about 35° C., about 30° C., about 25° C., about 20° C., about 15° C., about 10° C., about 5° C., about 1° C. and 0° C. In some embodiments, the temperature of the sputtering system 100 during the sputtering process is maintained at room temperature. Room temperature refers to a temperature to which humans are accustomed or have become acclimatized. In some embodiments, room temperature includes temperatures in the range of about 20° C.-27° C. and/or temperatures in the range of about 68° F.-80° F. In some embodiments, room temperature is 20° C., in some embodiments 25° C., in some embodiments 68° F., and in some embodiments 77° F.

In the embodiment depicted in FIG. 1, the metal oxide target 102 of the sputtering system 100 can be energized with a direct current (DC) energy source 110, a radio frequency (RF) or high frequency alternating current (AC) energy source 108, or both. The voltage applied by the energy source generates a plasma in one or more inert working gases near the cathode metal oxide target 102. As a result, metal and oxygen atoms are sputtered from the metal oxide target 102 and deposited onto the substrate 104.

As noted above, during the sputtering process, small concentrations of one or more inert working gases can be introduced into the sputtering system 100 to create a plasma 112 that helps to catalyze and/or otherwise enhance the sputtering process. During sputtering, the plasma 112 is maintained in an area along the surface of the cathode metal oxide target 102 by both the electrical charge put onto the cathode metal oxide target 102 and/or the magnetic field generated by the one or more magnets 106. The one or more inert working gas serves to provide a source of positive ions that are generated within the plasma 112 by the electric field. The positive ions are accelerated toward the metal oxide target 102 by the sputtering system 100 where they interact with and break apart the atoms and/or ions in the metal oxide target 102. The atoms and/or ions of the metal oxide target 102 are then ballistically driven toward the substrate 104. The target material 102 is thus slowly eroded and can be deposited as a coating 114 on the substrate 104.

The one or more inert working gases can be one or more of any inert gas that provides a suitable source of positive ions. In some embodiments, the one or more inert working gases are selected from any one or more of the Noble gases including, for example, helium, neon, argon, krypton, xenon, radon, and combinations thereof. In some embodiments, the inert working gas is argon. In some embodiments, small concentrations of oxygen gas can also be introduced into the sputtering system 100 during the sputtering process. In some embodiments, the inert working gases are argon and oxygen. In the embodiment depicted in FIG. 1, the inert working gases are argon, which provides a source of Ar⁺ ions, and oxygen.

During the sputtering process, small concentrations of one or more halogen and/or halogen-containing gases can be introduced into the sputtering system 100 in addition to the small concentrations of one or more inert working gases and oxygen gas. During sputtering, a fraction of the halogen is dissociated from the halogen gases or halogen-containing gases into the plasma generated by the inert working gases. This dissociation provides a source of reactive halogen ions into the sputtering system 100, which can be incorporated into the transparent conducting metal oxide film growing along the substrate 104 as a dopant. In some embodiments, the halogen gases are selected from fluorine gas, chlorine gas, bromine gas, iodine gas, astatine gas and combinations thereof. In some embodiments, the halogen gas is fluorine gas. In some embodiments, the halogen-containing gases are selected from carbon tetrafluoride gas, carbon tetrachloride gas, carbon tetrabromide gas, carbon tetraiodide gas, carbon tetraastatine gas and combinations thereof. In some embodiments, the halogen-containing gas is carbon tetrafluoride.

The sputtering process continues until a transparent conducting metal oxide film 114 of a desired thickness is grown on the substrate 104.

In some embodiments, after the sputtering process is complete the transparent conducting metal oxide film 114 is annealed. Annealing improves the conductivity of the transparent conducting oxide film. Annealing is a heat treatment process that alters certain properties of the transparent conducting oxide film, such as strength and hardness. Annealing occurs by the diffusion of atoms within the transparent conducting metal oxide film in response to the addition of heat energy, so that the film progresses toward its equilibrium state.

Both the time and temperature of the annealing step can be altered. In some embodiments, annealing can occur for a period of time ranging from about 1 minute to about 30 minutes. In some embodiments, annealing can occur for a period of time selected from about 30 minutes, about 25 minutes, about 20 minutes, about 15 minutes, about 10 minutes, about 5 minutes, about 4 minutes, about 3 minutes, about 2 minutes and about 1 minute.

In some embodiments, the annealing can occur at a temperature ranging from about 100° C. to about 500° C. In some embodiments, the annealing can occur at a temperature ranging from about 250° C. to about 500° C. In some embodiments, the annealing can occur at a temperature selected from about 500° C., about 450° C., about 400° C., about 350° C., about 300° C., about 250° C., about 200° C., about 150° C., about 100° C., about 50° C., about 10° C. and about 5° C.

In some aspects, the present disclosure relates to the generation of a transparent conducting oxide of tin oxide as the coating on a substrate which, in some embodiments, can be a halogen-doped tin oxide. The generation of a transparent conducting tin oxide film can occur via the sputtering method outlined above. When the sputtering method disclosed above is utilized, a transparent conducting tin oxide film coating having high conductivity can be generated on a substrate surface. In some embodiments, a transparent conducting tin oxide film can be generated via a sputtering process performed at room temperature, where room temperature is as defined above.

In some embodiments, and with reference to the general disclosure provided in FIG. 1, the metal oxide target material 102 is a tin-containing material. The tin-containing material can be any one or more of solid tin metal, a tin oxide material, a tin fluoride (SnF₂) material, or combinations thereof. During the sputtering process, low concentrations of both argon gas (Ar₂) and oxygen gas (O₂) can be introduced into the sputtering system 100 as inert working gases in order to form a plasma 112 near the tin-containing metal oxide material. Additionally, a low concentration of carbon tetrafluoride (CF₄) can be introduced into the sputtering system 100 as a halogen-containing gas in order to enhance the sputter deposition process and to act as a dopant in the growing transparent conducting tin oxide film.

In some embodiments, an RF power source can be used as the energy source 108 to drive the sputtering of the tin-containing metal oxide cathode target 102 and the deposition of the transparent conducting tin oxide film onto the anode substrate 104. The use of an RF power source may be particularly advantageous, as RF energy tends to maintain a larger plasma field 112 at the tin-containing metal oxide cathode 102. In some embodiments, an RF energy source may be superimposed on, or used in combination with, a DC power source to drive the sputtering system 100. The combination of the RF power source and the DC power source yields transparent conducting tin oxide films having good conductivity, smoothness, and hardness.

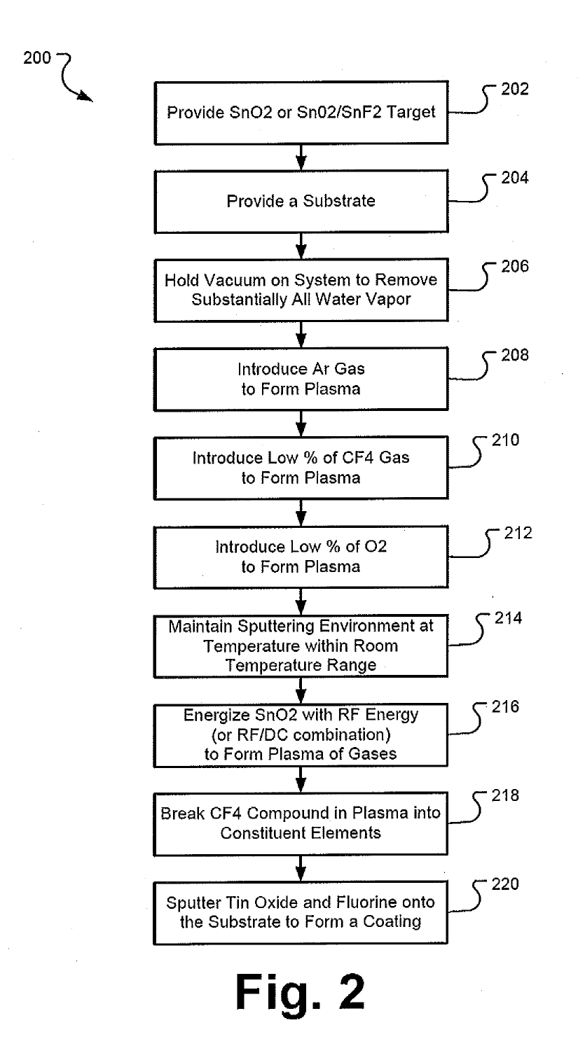

FIG. 2 provides a flow diagram comprising the steps of an exemplary sputtering process 200 according to the present disclosure. The depicted embodiment discloses a method of sputtering a transparent conducting metal oxide onto a substrate surface using a sputtering system such as that depicted in FIG. 1. In the initial step 202, a sputtering system is provided that includes a metal oxide target material contained within a sputtering chamber. In the depicted embodiment the metal oxide target material can be tin oxide or a composite target material comprising tin oxide and tin fluoride.

In step 204, a substrate, which will serve to receive the transparent conducting oxide film coating, is placed within the sputtering system. The sputtering system is then evacuated to operate under a vacuum, as shown in operation 206. The primary purpose of evacuation the creation of a vacuum in the sputtering system) is to remove as many non-desired gases from the sputtering system prior to sputtering, so that only the desired gases that are introduced into the sputtering system will react to generate the plasma. This avoids the generation of impurities in the plasma and, ultimately, the incorporation of impurities in the growing transparent conducting metal oxide film. The vacuum also creates a uniform environment in which sputtering may occur. The generation of a vacuum also serves to remove water vapor from the sputtering system, which is advantageous as high concentrations of water vapor present in the plasma may prevent the dissociation of the halogen from the halogen gases and/or the halogen-containing gases, which can reduce the rate of deposition of the conductive oxide film and reducing the resulting conductivity of the film. For example, a high level of water vapor may inhibit the dissociation or “cracking” of carbon tetrafluoride into its substituent components, thus reducing the amount of fluorine present to be available as a dopant.

Once the target and the substrate are in place and a vacuum has been established, one or more inert working gases are introduced into the system to form the plasma, as indicated in operation 208. In the depicted embodiment, the inert working gas is argon gas. In addition to the one or more inert working gases, one or more halogen gases or halogen-containing gases may be introduced into the sputtering system to form a part of the plasma and to provide a source of halogen ions which will act as a dopant in the resulting film, as indicated in operation 210. A low concentration of oxygen gas is also introduced into the system to form a part of the plasma, as shown in step 212.

In some embodiments it is desirable to maintain the sputtering system at a low temperature throughout the entirety of the sputtering process. For example, in the depicted embodiment the sputtering system is maintained at room temperature, as indicated in operation 214, where room temperature is as defined herein.

Once all of the desired gases have been introduced into the sputtering system, one or more power sources present in the sputtering system may be activated to initiate the sputtering process. In the depicted embodiment, the energy source is an RF energy source and sputtering is initiated by radio frequency energy to form the plasma and begin the deposition process, as indicated in operation 216.

During the sputtering process, the halogen may be dissociated from the one or more halogen gases or halogen-containing gases present in the plasma to provide a source of halogen ions which will act as a dopant in the growing conducting oxide film. In the depicted embodiment, carbon tetrafluoride gas may be dissociated or “cracked” and broken down into its constituent carbon and fluorine atoms, as well as carbon-fluorine fragments, as indicated in operation 218.

The energized halogen and metal oxide atoms and ions present in the plasma then move from the metal oxide target material to the substrate, where they deposit onto the substrate, as indicated in step 220. In the depicted embodiment, the halogen is fluorine and the metal oxide is tin oxide, which deposit onto the substrate surface to form a transparent conducting fluorine-doped tin oxide film on the substrate.

Finally, the sputter-coated substrate may be annealed as indicated in operation 222, to harden the transparent conducting metal oxide coating and further improve the conductivity as described herein.

### Dopants

A dopant is an impurity element that is added to a crystalline lattice, typically in low to moderate concentrations, to alter the optical and/or electrical properties of the crystal. A dopant works by altering the number of free electrons available in a crystal lattice, thereby making it more electrically conductive. For example, certain elements or compounds can be dried to form a uniform crystal lattice in which each atom bonds to an equal number of neighboring atoms. When a dopant with an excess of bonding electrons, for example 5 bonding electrons, is introduced, the result is free electrons present in the crystalline lattice, creating a negative charge. A dopant having three bonding electrons may be introduced to make holes in a crystalline lattice, creating a positive Charge.

Depending upon the concentration of added dopant, the dopant may or may not interfere with the formation of the crystalline lattice. At very low concentrations, for example at below about 4%, the presence of a dopant may not substantially interfere with the formation of a crystalline lattice. At low- to moderate concentrations, for example at about 4% to about 8%, a dopant may sufficiently interfere with the creation of the crystalline lattice so that the overall lattice is amorphous, with some crystals and/or crystallites remaining in the lattice. At high concentrations, for example at above 8%, a dopant may completely interfere with the creation of the crystalline matrix such that the lattice is completely amorphous.

In various aspects, transparent conducting metal oxides according to the present disclosure can be generated using one or more of a variety of dopants. As disclosed herein, during the sputtering process one or more halogen gases, and/or one or more halogen-containing gases, can be introduced into the sputtering chamber. When such gases are introduced, the energy present in the sputtering chamber from the one or more energy sources can cause the halogen to dissociate from the halogen gases and/or from the halogen-containing gases. The halogen is then free to move with the atoms and/or ions freed from the metal oxide target material to the substrate, where it will act as a dopant for the growing transparent conducting metal oxide film.

The halogen dopant may be one or more of any of the known halogens. In some embodiments, the halogen dopant is selected from fluorine, chlorine, bromine, iodine, astatine, and combinations thereof.

The transparent conducting metal oxide can thus be generated as a doped transparent conducting metal oxide on a substrate surface. The doped transparent conducting metal oxide can be generated from any one or more of many doped metal oxides. In some embodiments, the doped transparent conducting metal oxide is generated from one or more doped metal oxides selected from tin-doped indium-oxide, aluminum-doped zinc-oxide, indium-doped cadmium-oxide, fluorine-doped tin-oxide, and combinations thereof. In some embodiments, the doped transparent conducting metal oxide is generated from fluorine-doped tin-oxide.

In some embodiments, the doped transparent conducting metal oxide is generated from one or more halogen doped oxides of any one or more of the Period 4 or Period 5 transition metals including, without limitation, halogen doped scandium oxide, halogen doped titanium oxide, halogen doped vanadium oxide, halogen doped chromium oxide, halogen doped manganese oxide, halogen doped iron oxide, halogen doped cobalt oxide, halogen doped nickel oxide, halogen doped copper oxide, halogen doped zinc oxide, halogen doped gallium oxide, halogen doped germanium oxide, halogen doped yttrium oxide, halogen doped zirconium oxide, halogen doped niobium oxide, halogen doped molybdenum oxide, halogen doped technetium oxide, halogen doped ruthenium oxide, halogen doped rhodium oxide, halogen doped palladium oxide, halogen doped silver oxide, halogen doped cadmium oxide, halogen doped indium oxide, halogen doped tin oxide, halogen doped antimony oxide and combinations thereof. In some embodiments, the doped transparent conducting metal oxide is generated from halogen doped tin oxide.

### EXAMPLES

The following examples describe in detail certain properties of embodiments of transparent conducting metal oxides prepared by one or more of the sputtering methods disclosed herein. It will be apparent to those skilled in the art that many modifications, both to materials and methods, may be practiced without departing from the scope of the disclosure.

### Example 1

The conductivity of 16 individual transparent conducting metal oxide films generated according to the methods disclosed in FIGS. 1 and 2 was determined.

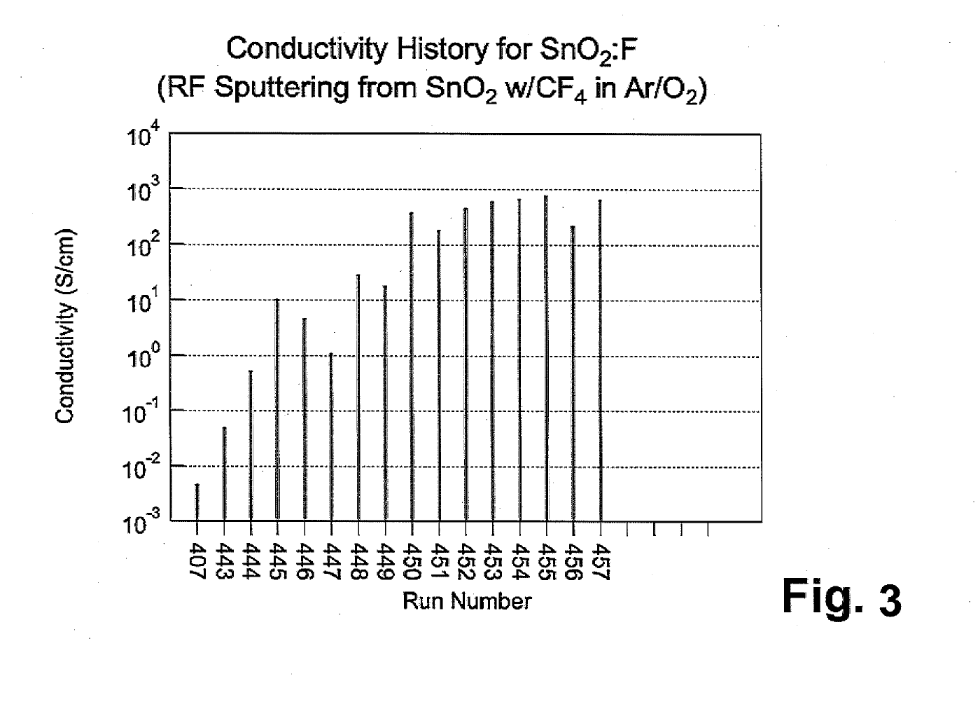

To generate each film, a tin oxide target material was utilized in a sputtering chamber, using RF energy as the sole energy source, in a plasma of argon gas, oxygen gas and carbon tetrafluoride gas. Each film was generated using the same protocol. The results are depicted in FIG. 3.

As indicated, the first eight transparent conducting tin oxide films generated, numbered 407-449, displayed low conductivity. This was primarily due to incorrect or varied gas ratios, the presence of water vapor in the chamber (which inhibited the dissociation of the carbon tetrafluoride gas), and high deposition temperatures.

However, as the results for the second eight transparent conducting tin oxide films, numbered 450-457, indicate, as the various parameters of the sputtering system are adjusted and optimized, the conductivity of the tin oxide deposition layers increased significantly.

The adjusted parameters are described in greater detail in the Examples that follow. However, some of the more significant adjustments made to the sputtering system include, without limitation: decreasing the amount of water vapor in the sputtering chamber to very low levels; decreasing the temperature of the sputtering chamber to room temperature and generally to less than about 100° C.; decreasing the concentration of oxygen gas introduced into the sputtering chamber, and thus into the plasma; decreasing the distance between the metal oxide target material and the substrate; and using an RF energy source, either alone or in conjunction with a DC energy source, rather than a DC energy source alone, to power the sputtering reaction.

Based on these data, it is apparent that transparent conducting metal oxide films, and particularly transparent conducting tin oxide films, that display high conductivity can be generated consistently using the sputtering deposition methods disclosed herein.

### Example 2

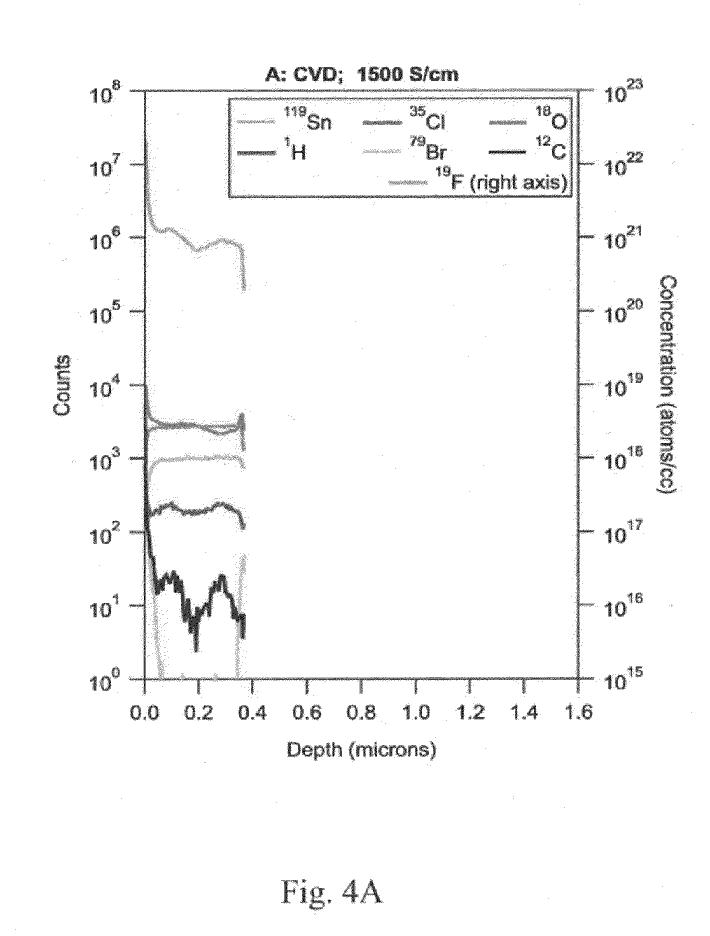

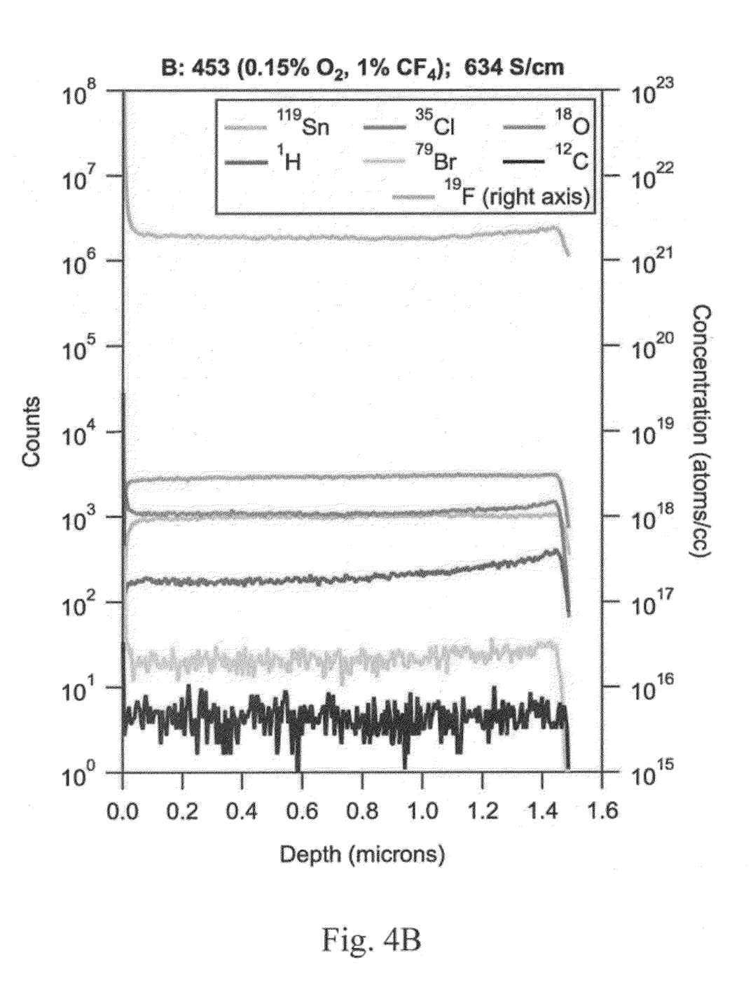

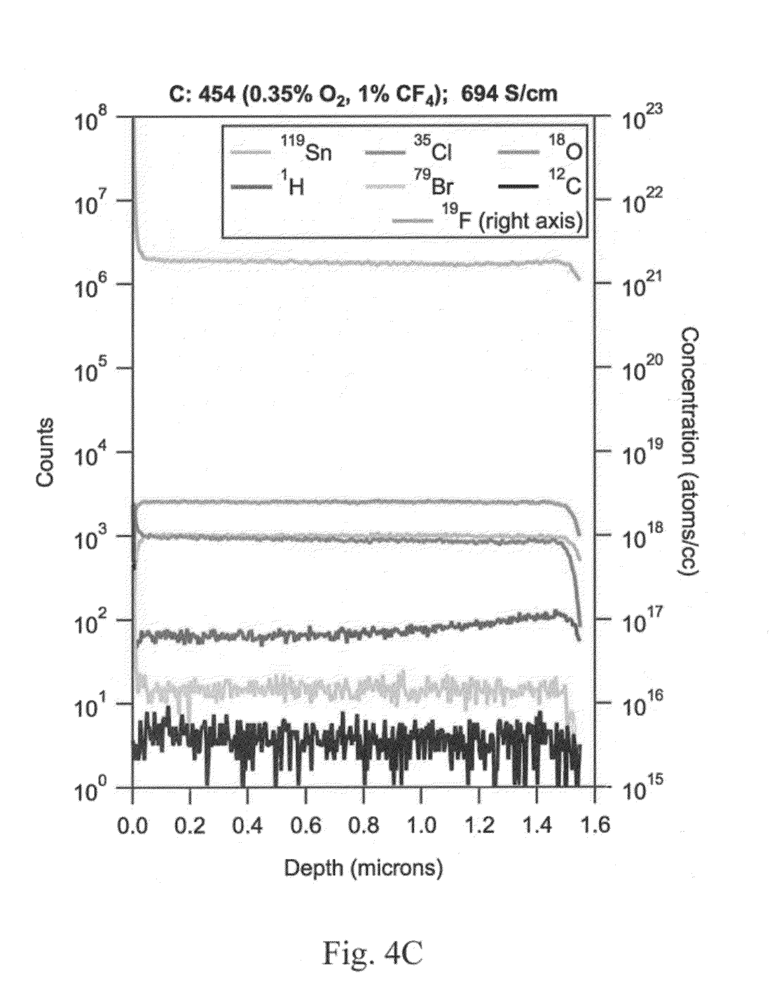

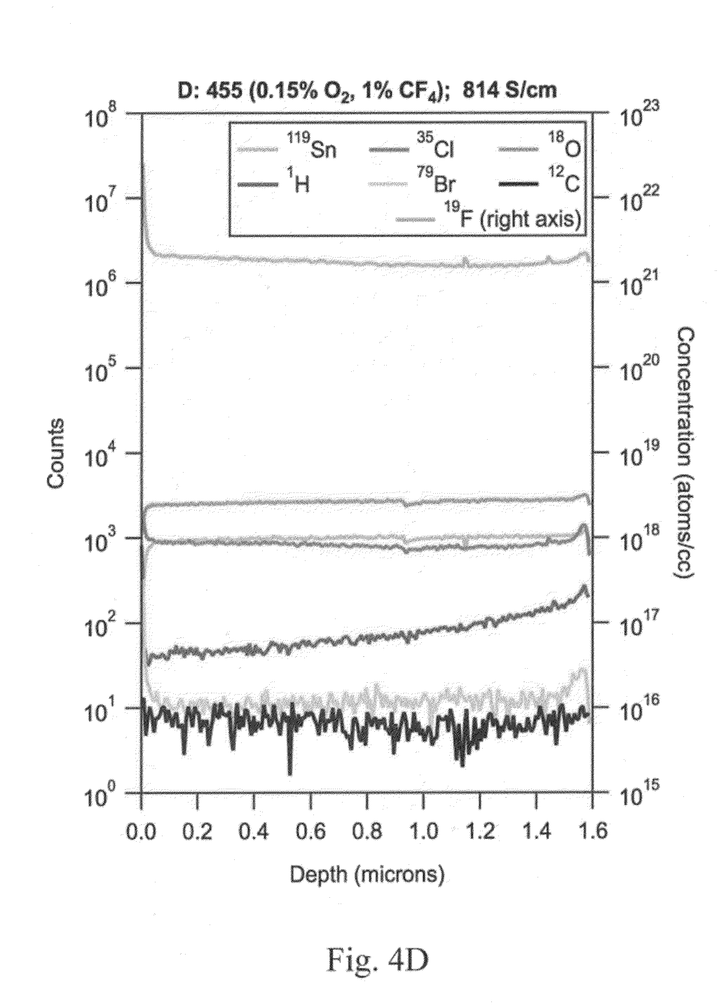

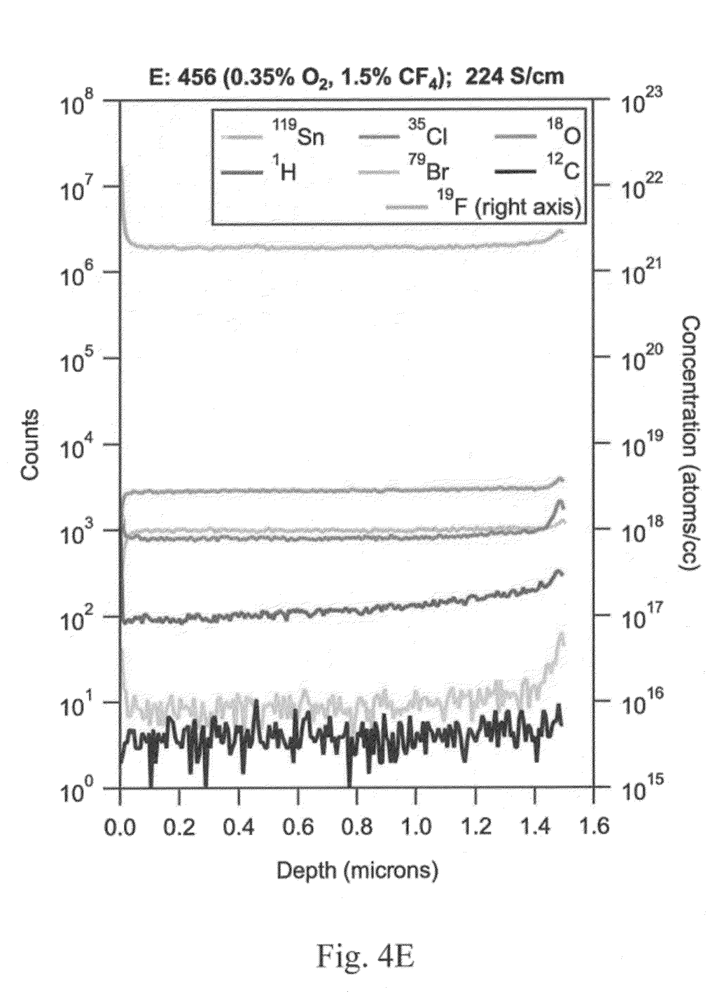

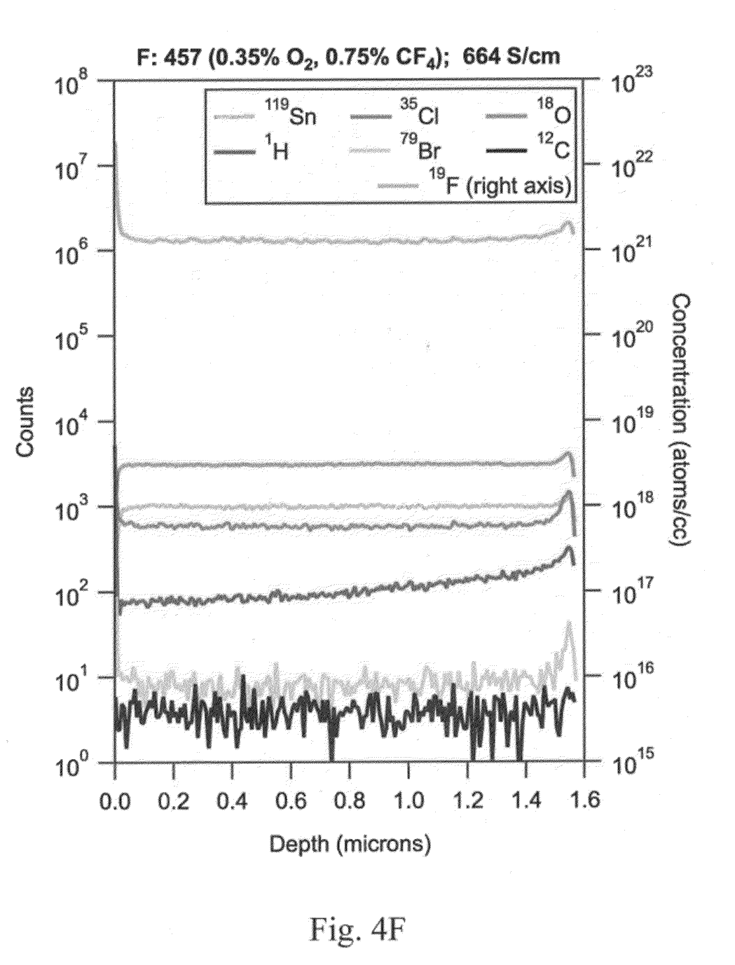

Secondary ion mass spectrometry (SIMS) measurements, and the resultant conductivity measurements, were obtained for five transparent conducting metal oxide films generated according to the sputtering methods disclosed herein. the results are shown in FIGS. 4A-4F.

FIG. 4A presents the SIMS measurement for a transparent conducting tin oxide film made using spray pyrolysis, a standard chemical vapor deposition (CVD) process. The data presented in FIG. 4A was used as a basis for comparison of the five transparent conducting metal oxides generated according to the sputtering methods disclosed herein, as the CVD process creates a transparent conducting metal oxide layer with high conductivity, on the order of 1,500 S/cm, as indicated.

Five of the transparent conducting tin oxide films generated for the previous Example, sample nos. 453, 454, 455, 456 and 457, were tested. The results are shown in FIGS. 4B-4F. During the generation of each of these transparent conducting tin oxide films, the concentration of oxygen gas and the concentration of carbon tetrafluoride gas introduced into the sputtering chamber during the sputtering process was varied, as shown.

As indicated in FIG. 4B, to generate transparent conducting tin oxide film number 453, during the sputtering process the oxygen content of the plasma was 0.25% and the carbon tetrafluoride concentration was 1%. As indicated in FIG. 4C, to generate transparent conducting tin oxide film number 454, during the sputtering process the oxygen content of the plasma was 0.35% and the carbon tetrafluoride concentration was 1%. As indicated in FIG. 4D, to generate transparent conducting tin oxide film number 455, during the sputtering process the oxygen content of the plasma was 0.15% and the carbon tetrafluoride concentration was 1%. As indicated in FIG. 4E, to generate transparent conducting tin oxide film number 456, during the sputtering process the oxygen content of the plasma was 0.35% and the carbon tetrafluoride concentration was 1.5%. And as indicated in FIG. 4F, to generate transparent conducting tin oxide film number 457, during the sputtering process the oxygen content of the plasma was 0.35% and the carbon tetrafluoride concentration was 0.75%.

What is notable in comparing the SIMS measurements of each of films numbered 453, 454, 455, 456 and 457 to the CVD film of FIG. 4A, is that the level of fluorine ion in each of the test films generated by the sputtering methods disclosed herein is substantially consistent. However, even with comparable levels of fluorine ion present, the conductivity of each of the samples varies widely.

What is apparent from these data is that changing both the oxygen gas and carbon tetrafluoride gas concentrations in the plasma can have significant effects on the ultimate conductivity of the resulting transparent conducting tin oxide film. For example, the results depicted in FIG. 4E show a very low conductivity of 224 S/cm, based on a relatively high oxygen gas and carbon tetrafluoride gas environment during sputtering. However, conductivity significantly improves, as shown in FIG. 4F, when the concentration of carbon tetrafluoride gas is cut in half from 1.5% to 0.75%, resulting in a conductivity measurement of 664 S/cm. The multiple reaction pathways for carbon, fluorine, and oxygen in the plasma may explain this observation. Too much carbon tetrafluoride gas in the plasma may lead to a loss of oxygen in the growing film due to The formation of CO and CO₂ in the plasma, plus formation of HF.

Similarly, by reducing the concentration of oxygen gas in the plasma, the conductivity measurement of samples rises. As can be seen when comparing the data presented in FIGS. 4B, 4C and 4D (where the concentration of the carbon tetrafluoride gas is kept constant at 1%), dropping the oxygen gas concentration to 0.15% significantly increases the conductivity of the sample to 814 S/cm (FIG. 4D).

Thus, the levels of both fluorine ions and oxygen ions that are available in the plasma can significantly affect the conductivity of the resulting transparent conductive tin oxide films, even though the absolute concentration of fluorine ion and oxygen ion in the resulting films remains fairly constant. Oxygen vacancies and fluorine (or other halogen) ions both act as dopants in the growing tin oxide films, but also decrease the crystallinity and long-range order in the films. Therefore, the optimum conductivity may be achieved with relatively low concentrations of oxygen gas and carbon tetrafluoride gas in the plasma.

### Example 3

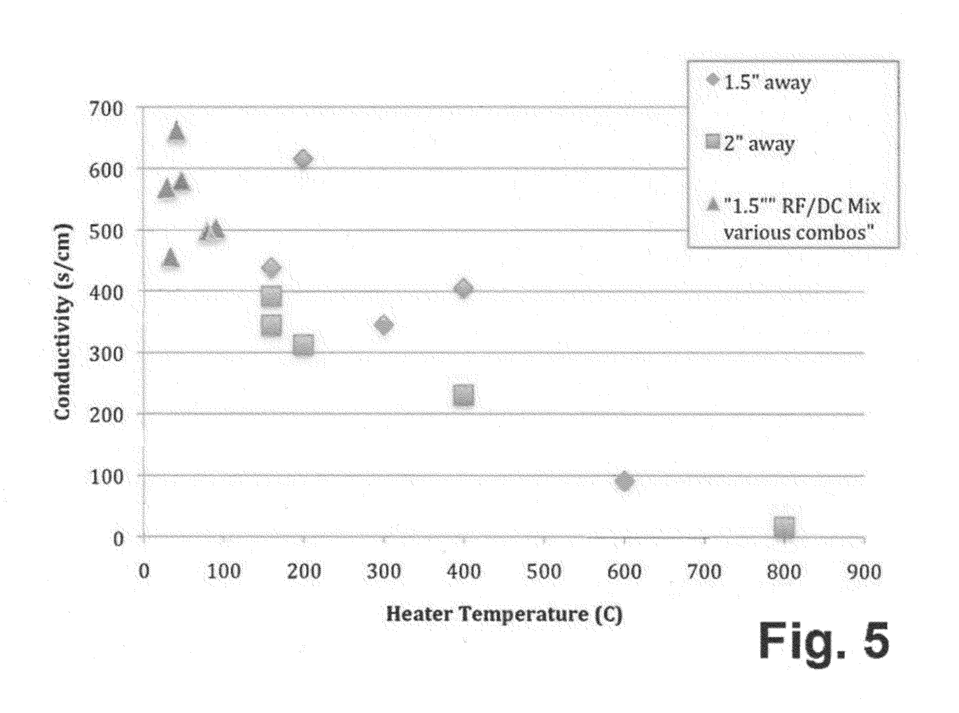

The effect of the temperature of the sputtering chamber during the sputtering process was evaluated, as was the effect of varying the distance between the metal oxide target material and the substrate during sputtering. The data are presented in FIG. 5. The data were generated using transparent conducting tin oxide films generated via the sputtering processes disclosed herein using both an RF energy source as the sole power source for the sputtering process, and a combination of an RF energy source and a DC energy source.

The data points represented by diamonds indicate the conductivity for transparent conducting tin oxide films generated using only an RF energy source at relatively high temperatures, between 150° C. and 600° C. The square data points represent the conductivity for transparent conducting tin oxide films generated using only an RF energy source at a distance of two inches between the target material and the substrate, and at significantly higher temperatures, between 150° C. and 800° C. The triangular data points indicate the measured conductivity for transparent conducting tin oxide films generated using a combination of RF and DC energy sources with the target and the substrate spaced one-and-a-half inches apart, and performed at a relatively low temperature range, less than 100° C. The specific data for each of these transparent conducting tin oxide films is presented in Table 1.

TABLE 1
RF/DC Deposited Samples
(SnO₂ Target)
Deposition Time = 10 min; Ar = 14.15 sccm; O₂ = 0.075 sccm;
CF₄ = 0.475 sccm; Target-Substrate Separation = 1.5 in)

| | | Power | | Conductivity |
|---|---|---|---|---|
| | Temperature | RF/DC | Ellipsometry | Rₛ (Ω/sq)/ |
| | (° C.) | (W) | (nm) | σ(S/cm) |
| Sample 1 | 38.7 | 100/25 | 773 | 56/498 |
| Sample 2 | 40.4 | 100/25 | 361 | 42/660 |
| Sample 3 | 39.6 | 75/50 | 430 | 41/567 |
| Sample 4 | 41.4 | 80/20 | 271 | 81/456 |
| Sample 5 | 37.8 | 100/25 | 359 | 48/580 |
| Sample 6 | 41.6 | 100/25 | 362 | 55/502 |

The data presented in Table 1 and FIG. 5 demonstrate that as the temperature of the sputtering chamber, and thus the temperature of the substrate surface, is decreased, the conductivity of the transparent conducting tin oxide films deposited onto the substrate improves. In particular, the conductivity is significantly higher when the sputtering process takes place at room temperature. The transparent conducting tin oxide films generated using combined RF/DC energy sources have a higher conductivity, which may be due to the combination of the higher carbon tetrafluoride cracking efficiency of the RF fraction with the higher deposition rate, and the associated enhanced fluorine-incorporation, of the DC fraction.

### Example 4

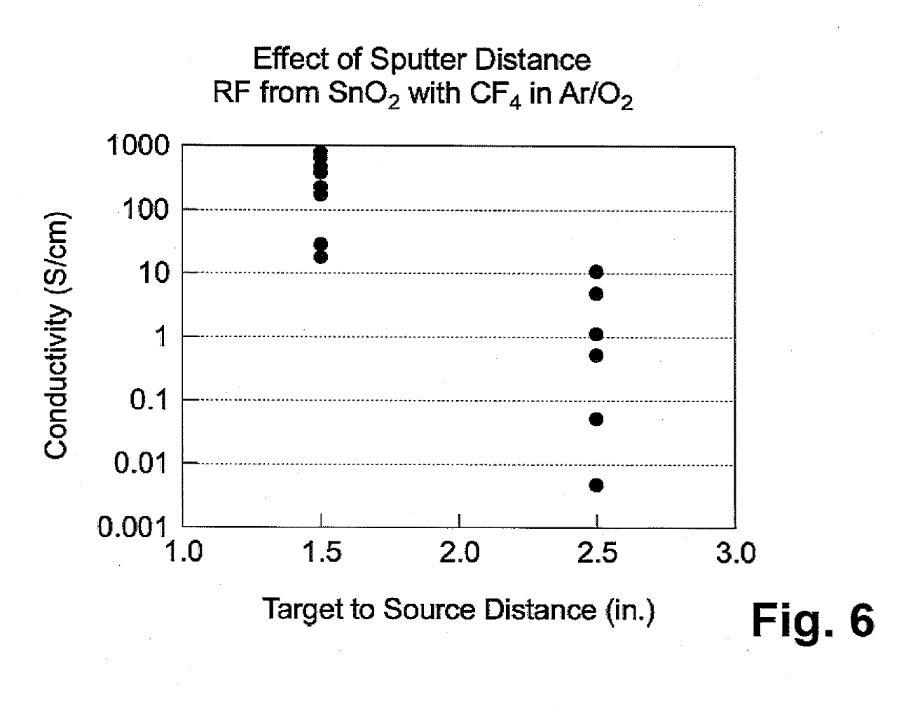

The effect on the conductivity of the transparent conducting tin oxide films of varying the distance between the metal oxide target material and the substrate during the sputtering process was further evaluated. The results are depicted in FIG. 6.

Specifically, FIG. 6 shows the results of sputtering deposition of a transparent conducting tin oxide film onto a substrate in an argon gas plasma, with varying concentrations of oxygen gas and carbon tetrafluoride gas, at varying distances between the metal oxide target material and the substrate.

The data indicate that the plasma concentrations do have some effect on the relative conductivity of the transparent conducting tin oxide films. Additionally, the conductivity of the transparent conducting tin oxide films increased as the distance between the metal oxide target material and the substrate surface is reduced from 2.5 inches to 1.5 inches.

As can be seen in FIG. 5, separating the metal oxide target material and the substrate 2.5 inches during the sputtering process yields a significant impact in the resulting conductivity of the transparent conducting film. Thus, a range of separation of the metal oxide target material and the substrate on the order of 1-1.5 inches during sputtering will result in an increase in the ultimate conductivity of the final transparent conducting metal oxide film.

### Example 5

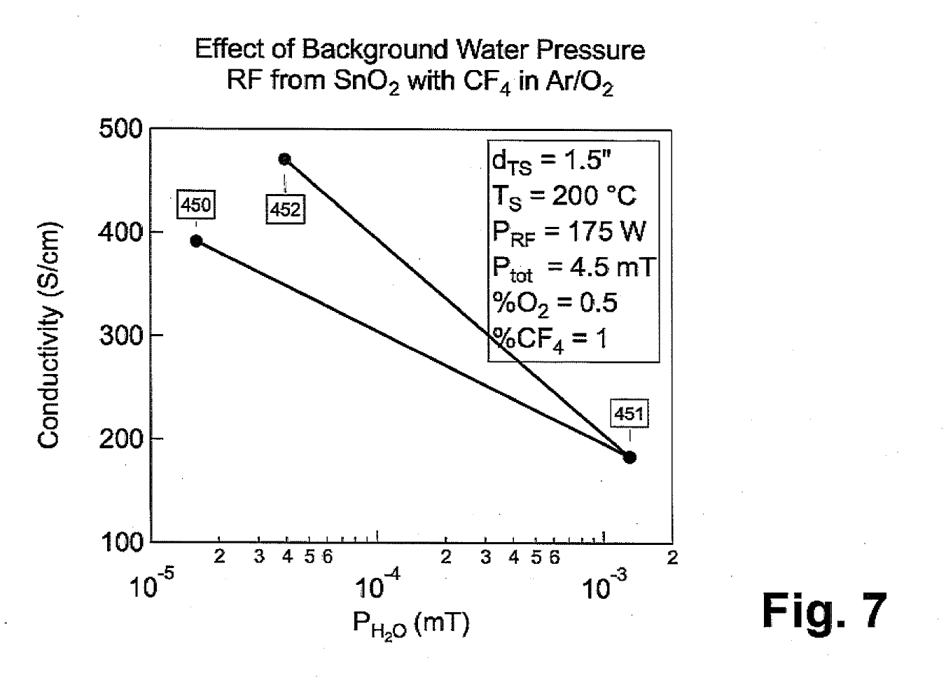

The effects of water vapor pressure, and particularly the total amount of water vapor present inside of the sputtering chamber during the sputtering process, on the conductivity of the resulting transparent conducting metal oxide films was evaluated. The results are presented in FIG. 7.

To generate the transparent conducting oxides used in this Example, a sputter deposition process disclosed herein was performed at a temperature of 200° C. using an RF energy source of 175 watts and a separation distance between the metal oxide target material and the substrate of 1.5 inches. The concentration of oxygen gas in the plasma was set at 0.5% and the concentration of carbon tetrafluoride gas was set at 1%. The total pressure in the sputtering chamber was reduced to 4.5 mT and a very low water vapor pressure was achieved inside of the sputtering chamber by extending the time taken for the vacuum process to evacuate the chamber.

As shown in FIG. 7, the two data points reflecting significantly higher conductivity (point 450 and 452) correlate to transparent conducting tin oxide films generated at very low water vapor pressures, on the order of 1×10⁴ mT and 4×10⁴ mT, respectively. In contrast, a third transparent conducting tin oxide film generated at a water vapor pressure on the order of about 100 mT (point 451) displayed lower conductivity.

Therefore, the transparent conducting tin oxide films created at the lower water vapor pressures displayed over twice the conductivity as the transparent conducting tin oxide film created at the higher water vapor pressure.

### Example 6

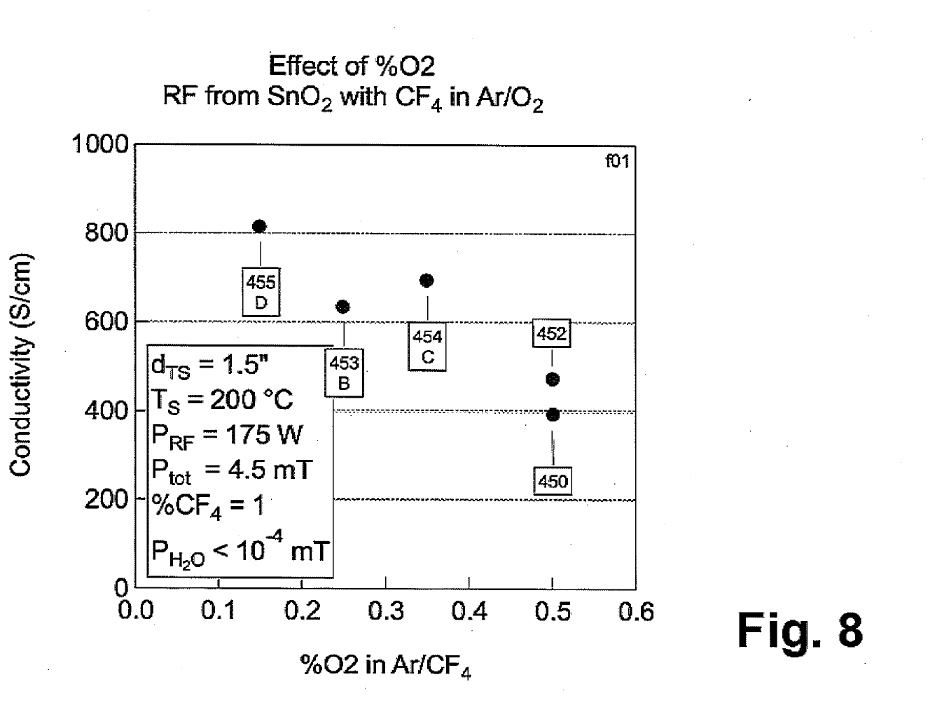

The effects of changing the concentration of oxygen gas in the plasma during the sputtering process was evaluated. The results are depicted in FIG. 8.

To generate the five transparent conducting oxide films used in this Example, a sputter deposition process disclosed herein was performed whereby the distance between the metal oxide target material and the substrate was 1.5 inches, the temperature of the sputtering chamber was maintained at 200° C. throughout the sputtering process, the power to the system was exclusively generated by an RF energy source provided at 175 watts, the percentage of carbon tetrafluoride gas was held steady at 1%, the total pressure of sputtering chamber was reduced to 4.5 mT, and the partial pressure of the water vapor component inside of the sputtering chamber was reduced to below 10⁻⁴ mT. Thus, the only variant was the concentration of oxygen gas introduced into the plasma during sputtering.

As can be seen in FIG. 8, as the concentration of oxygen gas was reduced, the conductivity of the transparent conducting oxide films increased significantly. At a concentration of 0.15% oxygen, the conductivity was measured at over 800 S/cm.

### Example 7

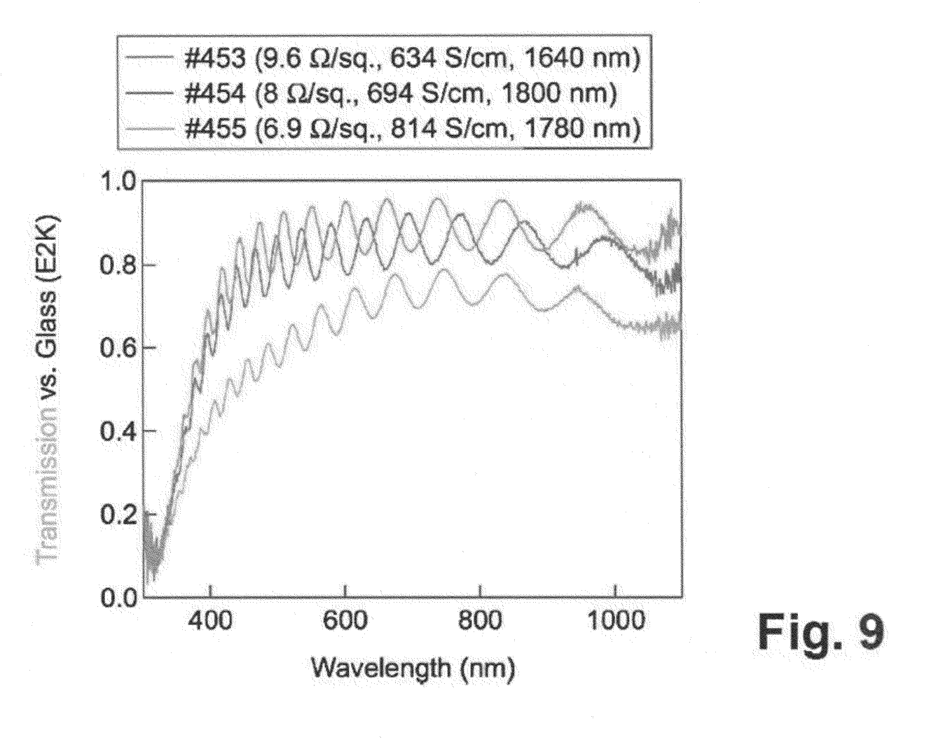

The transmission characteristics of three transparent conducting tin oxide films (sample nos. 902, 904 and 906) across the visible wavelength spectrum was determined. The transparency of each of the samples was measured, using a glass that was allocated a transmission value of 1 as the basis for comparison. The results are depicted in FIG. 9.

The first sample 902, displaying the highest transparency, was the thinnest deposition sample at 1,640 nm based upon ellipsometry measurements. This sample had the highest surface resistance of 9.6 Ω/sq and the lowest conductivity at 634 S/cm.

The second sample 904 had the second highest transparency values across the visible spectrum and was a slightly thicker deposition sample at 1,800 nm based upon ellipsometry measurements. This sample had a lower surface resistance of 8 Ω/sq and thus a higher conductivity of 694 S/cm.

The third sample 906 had the least transparency across the visible spectrum but had the highest conductivity at 814 S/cm, while its thickness remained on the same order as the first two samples at 1,780 nm.

Thus, it appears that there may be some tradeoff in transparency of a transparent conducting tin oxide film as conductivity improves, especially at very high doping levels.

### Example 8

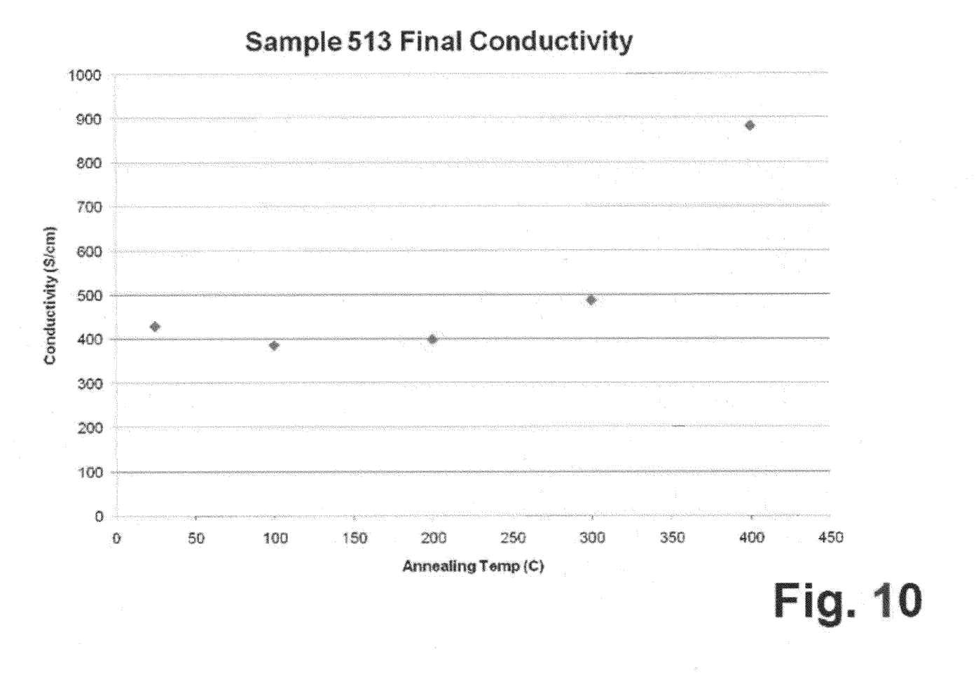

A study of the annealing processes disclosed herein was performed on a transparent conducting iron oxide film produced via an RF energy source powered, room temperature sputtering process as described herein. In this Example, a single transparent conductive iron oxide film was generated and then divided into five separate pieces that were each separately annealed in an argon gas environment for 15 minutes at five different temperatures. The results are depicted in FIG. 10.

The data presented in FIG. 10 demonstrates that the use of annealing temperatures above 200° C. increases the conductivity of the transparent conductive iron oxide films. Generally, as the annealing temperature increases, conductivity also significantly increases. As can be seen, annealing one of the samples at 400° C. for 15 minutes resulted in a final conductivity of slightly under 900 S/cm, which is similar to the conductivity displayed by the conductive tin oxide film created by a CVD process depicted in FIG. 4A. Additionally, the annealing process tends to increase the hardness and durability of the transparent conductive iron oxide films, thus providing a more resilient conductive coating on the substrate. An increase in conductivity was also seen for transparent conductive iron oxide films annealed in an oxygen atmosphere, but the magnitude of the increase in conductivity was lower.

### Example 9

Additional annealing experiments were conducted on transparent conductive iron oxide films produced according to the sputtering methods disclosed herein. The results are presented in Tables 2, 3 and 4, below. Table 2 presents the results of annealing for six different transparent conductive iron oxide film samples that were generated using slight variations in the concentration of oxygen gas during the sputtering process. The concentration of oxygen gas was varied by altering the flow rate of oxygen gas during the sputtering process.

In the experiment represented by Table 2, the transparent conductive iron oxide films were generated using a sputtering process having a DC energy source, at a temperature of 200° C. for 4 minutes, and at a pressure inside of the sputtering chamber of 6.6×10⁻⁶ Torr. The thickness of each of the resulting transparent conductive iron oxide films was between 720 nm and 1000 nm.

An annealing process was performed after the generation of the films at a temperature of 245° C. for 10 minutes. As noted in Table 2, the conductivity (presented as both the sheet resistance and conductivity) for these samples was quite low before annealing, between 50 S/cm and 215 S/cm.

TABLE 2
DC Deposited Samples
(SnO₂ + SnF₂ Composite Target)
Temperature = 200° C.; Deposition Time =
4 min; Base Pressure = 6.6 × 10⁻⁶ Torr

| | | | | Conductivity |
|---|---|---|---|---|
| | Ar Flow Rate | O₂ Flow Rate | Ellipsometry | Rₛ (Ω/sq)/ |
| | (sccm) | (sccm) | (nm) | σ(S/cm) |
| Sample 1 | 38.7 | 8 | 735 | 94/107 |
| Sample 2 | 40.4 | 6 | 805 | 100/138 |
| Sample 3 | 39.6 | 7 | 788 | 61/201 |
| Sample 4 | 41.4 | 5 | 814 | 68/186 |
| Sample 5 | 37.8 | 9 | 721 | 58/214 |
| Sample 6 | 41.6 | 4 | 993 | 89/153 |

However, after annealing the conductivity of Sample 1 from Table 2 improved dramatically, as indicated in Table 3. In Table 3, the results of point-to-point resistance taken at 0.5 cm increments across the diagonal of Sample 1, both before and after annealing, are presented. As indicated, pre-annealing resistance is high, from slightly less than 1 kΩ in the center to up to 40 kΩ toward the edges of the sample.

After annealing, the resistance across Sample 1 drops dramatically to slightly more than 100Ω in the center to up to about 500Ω on the edges. These low resistance measurements reflect high conductivity for Sample 1 after annealing, as conductivity is inversely proportional to resistance,

TABLE 3
Annealed DC Deposited Sample 1 from Table 2
Point-to-Point Resistance
(0.5 cm spacing across diagonal)
Anneal Temp = 245° C.; Anneal Time = 10 min

| | | After Annealing |
|---|---|---|
| | As Grown | (245° C.; 15 min; Ar gas) |
| Position | kΩ | Ω |
| 1-2 | 32.5 | 285 |
| 2-3 | 41.1 | 514 |
| 3-4 | 3.87 | 147 |
| 4-5 | 1.11 | 120 |
| 5-6 | 0.896 | 112 |
| 6-7 | 0.878 | 111 |
| 7-8 | 1.02 | 123 |
| 8-9 | 2.19 | 140 |
| 9-10 | 14.7 | 273 |
| 10-11 | 33.5 | 480 |
| 11-12 | 15.1 | 270 |
| 12-13 | 3.85 | 240 |

Additionally, four-point resistance measurements were taken of Sample 1 after annealing with the following results: center of film=59.6 Ω/sq; intermediate ring around center=230 Ω/sq; and corner of film=161 Ω/sq. As with the point-to-point resistance measurements, these sheet resistance measurements are likewise low;

In another experiment, a wafer was sputter-deposited with a film coating of a transparent conducting tin oxide using a combination of DC and RF power sources and a SnO₂ metal oxide target. Table 4 shows a comparison of point-to-point resistance measurements at 0.5 cm increments taken diagonally across the film. A comparison of the results of Table 4 with the data presented in Table 3 shows a significant decrease in initial resistance of the transparent conducting tin oxide film after deposition with the combined RF/DC energy sources as compared to the data of the DC-only energy deposition samples of Table 3. Specifically, a difference of approximately 3 orders of magnitude can be seen.

Even with the low resistance properties achieved by the combined RF/DC energy source sputtering process, annealing at 350° C. for 15 minutes in an argon environment still decreased resistance and increased conductivity by 25-35%.

TABLE 4
DC + RF Sputtering—Point-to-Point Resistance
(SnO₂ target; 0.5 cm spacing across diagonal)

| | | After Annealing |
|---|---|---|
| | As Grown | (350° C.; 15 min; Ar gas) |
| Position | Ω | Ω |
| 1-2 | 94 | 60 |
| 2-3 | 83 | 52 |
| 3-4 | 65 | 46 |
| 4-5 | 59 | 40 |
| 5-6 | 53 | 37 |
| 6-7 | 50 | 34 |
| 7-8 | 50 | 37 |
| 8-9 | 53 | 37 |
| 9-10 | 58 | 40 |
| 10-11 | 63 | 44 |
| 11-12 | 72 | 50 |
| 12-13 | 86 | 51 |

Thus, as shown above, RF or RF/DC-combined sputter deposition of transparent conductive fluorine-doped tin oxide films on substrates is possible at low temperatures, particularly at room temperature, and results in films having higher conductivity than what was previously achievable using known processes. Optimization of several parameters including, for example, sputtering at a reduced temperature (or room temperature); introduction of oxygen gas and halogen gases or halogen-containing gases into the plasma at low concentrations; removing water vapor from the sputtering chamber to very low concentrations; minimizing the separation distance between the metal oxide target material and the substrate; the use of RF energy or a combination of RF and DC energy to ionize the system; and annealing the resulting transparent conducting metal oxide film for a short period of time; leads to the surprising results presented herein. Potential benefits of the sputtering processes disclosed herein include increased speed of film deposition as well as decreased cost, as the disclosed sputtering processes can be readily implemented into a manufacturing process line. Further, transparent conducting metal oxide films produced according to the disclosed sputtering methods can be prepared and deposited onto numerous substrates that were previously unable to be coated by other processes, such as spray pyrolysis or CVD processes, because the substrate materials could not withstand the high temperatures required for such processes. The disclosed sputtering deposition processes open up many options for low cost coating of a variety of substrates with transparent conducting oxides having relatively high conductivity for a variety of electrical, optical, and semiconductor materials, among others.

Finally, it should be noted that there are alternative ways of implementing the embodiments disclosed herein. While a number of exemplary aspects and embodiments have been discussed above, those of skill in the art will recognize certain modifications, permutations, additions and sub combinations thereof. Accordingly, the present embodiments are to be considered as illustrative and not restrictive. Furthermore, the claims are not to be limited to the details given herein, and are entitled their full scope and equivalents thereof.

What is claimed is:

1. A method for sputter deposition of a tin-oxide film onto a substrate, comprising:
providing a tin compound in a sputtering chamber;
providing a substrate in the sputtering chamber;
introducing at least one inert gas into the sputtering chamber;
maintaining the temperature of the sputtering chamber below about 100° C.;
energizing the tin compound and the at least one inert gas with radio frequency energy; and
sputtering the tin oxide as a film onto the substrate.

2. The method of claim 1, further comprising annealing the tin-oxide film.

3. The method of claim 1, comprising energizing the tin compound with direct current concurrently with the radio frequency energy.

4. The method of claim 1, wherein the tin compound is selected from tin metal, tin oxide, tin fluoride, and combinations thereof.

5. The method of claim 1, further comprising, prior to the step of energizing:
introducing at least one gas selected from halogen gases and halogen-containing gases into the sputtering chamber;
energizing the halogen gas with the radio frequency energy; and
sputtering the halogen from the at least one gas onto the substrate concurrently with the tin oxide.

6. The method of claim 5, wherein the halogen is annealed concurrently with the tin-oxide film.

7. The method of claim 5, wherein the at least one gas is fluorine gas or carbon tetrafluoride gas.

8. The method of claim 1, further comprising introducing oxygen gas into the sputtering chamber prior to the step of energizing.

9. The method of claim 1, wherein the inert gas is argon gas.

10. The method of claim 1, comprising placing the sputtering chamber under a vacuum.

11. A method of generating a metal oxide film on a substrate, comprising:
placing a metal oxide target material in a sputtering chamber;
placing a substrate in the sputtering chamber at a distance from the metal oxide target;
introducing at least one inert gas into the substrate chamber;
adjusting the temperature of the sputtering chamber to below about 100° C.;
energizing the metal oxide target and at least one inert gas via an energy source; and
sputtering atoms from the metal oxide target onto the substrate.

12. The method of claim 11, further comprising annealing the tin-oxide film.

13. The method of claim 11, wherein the metal oxide is selected from indium oxide, zinc oxide, cadmium oxide, tin oxide and combinations thereof.

14. The method of claim 11, wherein the substrate is selected from glass, ceramic, plastic, a silicon wafer, a photovoltaic cell and a semiconductor.

15. The method of claim 11, wherein the inert gas is selected from oxygen gas, helium gas, neon gas, argon gas, krypton gas, xenon gas, radon gas, and combinations thereof.

16. The method of claim 11, wherein the energy source is selected from pulsed direct current (DC), non-pulsed DC, alternating current (AC), high frequency AC/radio frequency (RF) energy, RF energy superimposed with DC, and combinations thereof.

17. The method of claim 11, wherein the temperature of the sputtering chamber is room temperature.

18. The method of claim 11, further comprising, prior to the step of energizing, introducing at least one gas selected from halogen gases and halogen-containing gases into the sputtering chamber.

19. The method of claim 18, wherein the halogen from the at least one gas is sputtered onto the substrate.

20. The method of claim 18, wherein the halogen gases are selected from fluorine gas, chlorine gas, bromine gas, iodine gas, astatine gas and combinations thereof and the halogen-containing gases are selected from carbon tetrafluoride gas, carbon tetrachloride gas, carbon tetrabromide gas, carbon tetraiodide gas, carbon tetraastatine gas and combinations thereof.
